(19) United States
(12) Patent Application Publication
(10) Pub. No.: US 2009/0302770 A1
(43) Pub. Date: Dec. 10, 2009

(54) Circuit for compensating thermal variations, lamp, lighting module and method for operating the same

(75) Inventors: Michael Weis, Munich (DE); Jens Richter, Hagelstadt (DE)

Correspondence Address: Viering, Jentschura & Partner - OSR, 3770 Highland Ave., Suite 203, Manhattan Beach, CA, 90266, US

(73) Assignee: OSRAM GmbH, Munchen (DE)

(21) Appl. No.: 12/421,724

(22) Filed: Apr. 10, 2009

(30) Foreign Application Priority Data
Apr. 10, 2008 (DE) 10 2008 018 236.2

(51) Int. Cl. H05B 37/02; H03K 3/42

(52) U.S. Cl. 315/185 R; 315/309; 315/294; 327/513

(57) ABSTRACT

A circuit for adjusting and for at least partially compensating, respectively, thermal variations is provided, where a current source is connected to a temperature compensation unit, where the temperature compensation unit at least partially compensates thermal variations of the current source, wherein the temperature compensation unit has at least one device having a temperature coefficient, in particular having a negative temperature coefficient. Further a lighting module or a lamp may have such a circuit as well as a method for operating the circuit and/or the lamp and the lighting modules, respectively.

### CROSS-REFERENCE TO RELATED APPLICATIONS

This application claims priority to German Patent Application No. 10 2008 018 236.2, filed Apr. 10, 2008. The complete disclosure of the above-identified application is hereby fully incorporated herein by reference.

### TECHNICAL FIELD

The invention relates to a circuit for compensating thermal variations, a lamp or a lighting module as well as a method for operating the same.

### BACKGROUND

Particularly with regard to lighting purposes light emitting diodes (LEDs) may be employed. In particular, a light of a lighting unit or a lamp particularly may be caused by an interaction of spectra emitted by different light emitting diodes.

Here, it turns out to be problematic that the light emitting diodes as well as the electronics warm up heavily due to the high power density and that the spectrum emitted by the light emitting diode drifts due to the heating. In this respect, the spectrum emitted by a light emitting diode is dependent on a cross current (via the light emitting diode) and on a substrate temperature of the light emitting diode.

A further problem concerning the usage of high power light emitting diodes exists in variations of the forward bias at a defined cross current caused by manufacturing processes. The variations caused by manufacturing processes result in voltage differences, which in turn fall off via a current source for feeding the light emitting diode and therefore may result in considerable power dissipation.

Also, a problem exists in suitably adjusting the current for the light emitting diode(s).

### SUMMARY

According to various embodiments, the previously described disadvantages can be avoided and in particular a circuit can be provided which allows for a efficient and improved potential for operating a lighting unit and which at least partially compensates a thermal interdependence of the components.

According to an embodiment, in a circuit for adjusting and at least partially compensating, respectively, thermal variations, a current source is connected to a temperature compensation unit, the temperature compensation unit at least partially compensates thermal variations of the current source, and the temperature compensation unit comprises at least one device having a temperature coefficient, in particular having a negative temperature coefficient.

According to a further embodiment, a current of the current source may be alterable. According to a further embodiment, a connection in series comprising the device and a first resistor may be connected in parallel with a second resistor and a voltage falling off at this parallel connection may serve as an input value for the current source. According to a further embodiment, the device may comprise at least one of the following components: a diode; a Schottky diode; a high-temperature conductor. According to a further embodiment, the current source may provide an output current which may be amplified by means of a driver unit. According to a further embodiment, the temperature compensation unit may be connected to the driver unit. According to a further embodiment, the current source and the temperature compensation unit may be connected to a control unit for a input voltage. According to a further embodiment, the control unit may be adjustable such that a voltage falling off across the current source and the driver unit results in no or marginal losses in the driver unit. According to a further embodiment, the voltage may be adjustable such that the driver unit may reach a pre-selectable amplification. According to a further embodiment, an output current of the driver unit may be fed to at least one lighting unit. According to a further embodiment, the lighting unit may comprise at least one light emitting diode, at least one string comprised of light emitting diodes and/or a parallel circuit thereof. According to a further embodiment, the plurality of light emitting diodes may be of a same type and/or have substantially the same color. According to a further embodiment, a brightness of the lighting unit may be adjustable by means of a pulse-width modulation.

According to another embodiment, a lighting module or a lamp may comprise a circuit as described above.

According to a further embodiment, the lighting module or lamp may comprise several lighting units. According to a further embodiment, a brightness and/or a directional characteristic of the lighting modules and the lamp, respectively, may be adjustable. According to a further embodiment, a chromaticity coordinate may be adjustable.

According to yet another embodiment, a method for operating a circuit may comprise the steps of: connecting a current source of the circuit to a temperature compensation unit of the circuit, and compensating at least partially thermal variations of the current source by the temperature compensation unit, wherein the temperature compensation unit comprises at least one device having a temperature coefficient.

According to yet another embodiment, a method for operating a lighting module or a lamp may comprise the steps of: arranging a circuit within the lighting module or lamp, connecting a current source of the circuit to a temperature compensation unit of the circuit, and compensating at least partially thermal variations of the current source by the temperature compensation unit, wherein the temperature compensation unit comprises at least one device having a temperature coefficient.

### BRIEF DESCRIPTION OF THE DRAWINGS

Exemplary embodiments of the invention will be illustrated and described in the following by means of the accompanying drawings, in which:

FIG. 1 shows a circuit comprising a vastly temperature compensated current source for operating a lighting unit;

FIG. 2 shows a detailed presentation of the part of the circuit of FIG. 1 meant for temperature compensation.

### DETAILED DESCRIPTION

As mentioned above, according to various embodiments, a circuit for adjusting and for at least partially compensating thermal variations, respectively, is provided
in which a current source is connected to a temperature compensation unit,
in which the temperature compensation unit at least partially compensates thermal variations of the current source,
wherein the temperature compensation unit comprises at least one device having a temperature coefficient, in particular having a negative temperature coefficient.

In particular, the current source may provide any, particularly variably adjustable constant currents. A further advantage exists in that the temperature compensation unit may comprise merely passive devices. Thus, the approach recommended herein provides a cost effective solution allowing for being responsive to thermal variations.

By compensating the thermal behavior of the cross current of the lighting unit the possibility arises to compensate, via further methods, the drift of the resulting spectrum by admixing further spectra. This is to mean that the thermal behavior of single light emitting diodes (serving as components for the lighting unit) can be described only via their own physical contexts and vastly is not influenced by the electronics.

The temperature compensation unit may comprise several devices having different temperature coefficients. In particular, the temperature compensation unit may comprise several devices whose thermal behavior is designed such that they compensate each other with respect to their characteristics.

According to a further embodiment, a current of the current source is alterable.

In particular, the current may be adjusted via a respective wiring of the current source.

In particular according to a further embodiment, a connection in series, comprising the device and a first resistor, is connected in parallel with a second resistor and a voltage present across this parallel connection serves as an input value for the current source.

Hereby thermal effects, also concerning components connected to the circuit, for example for a lighting unit supplied, may be compensated for extensively.

Preferably, the current source alters its output current such that the voltage across the parallel connection reaches a specific value.

According to a further embodiment, the device comprises at least one of the following components:
a diode;
a Schottky diode;
a high-temperature conductor.

According to a further embodiment, the current source provides an output current which may be amplified using a driver unit.

Any kind of amplifier may be used as the driver unit. For example, the driver unit may comprise a transistor or a transistor circuit for amplifying the signal.

By means of the driver unit the current supplied by the current source is amplified to result in the output current. This output current is utilized to operate a downstream component, for example a lighting unit.

According to a further embodiment, the temperature compensation unit is connected to the driver unit.

According to a further embodiment, the current source and the temperature compensation unit are connected to a control unit for a input voltage.

According to a further embodiment, the control unit is adjustable such that a voltage present across the current source and the driver unit leads to no or merely marginal losses in the driver unit.

In particular, this voltage may be adjustable such that the driver unit may reach a predetermined amplification. Preferably, the voltage provided is determined such that the driver unit may reach a predetermined amplification, in particular a saturation. Thereby it is allowed for that the driver unit, in line with its amplification, operates efficiently and optimized, respectively, but exceeding voltages and power losses resulting there from are minimized.

An alternative embodiment is designed such that a output current of the driver unit may be supplied to at least one lighting unit.

It is a further embodiment that the lighting unit comprises at least one light emitting diode, at least one string consisting of light emitting diodes and/or a connection in parallel thereof.

It is also an embodiment that the several light emitting diodes comprise a similar type and/or substantially similar color.

According to a further embodiment, a brightness of the lighting unit is adjustable by means of a pulse-width modulation.

According to yet other embodiments, a lighting module or a lamp may comprise the circuit described herein.

According to a further embodiment, the lighting module or the lamp comprise several lighting units.

According to a further embodiment, a brightness and/or a directional characteristic of the lighting module and the lamp, respectively, is adjustable.

It is in line with a further embodiment that a chromaticity coordinate of the lighting module and the lamp, respectively, is adjustable.

According to further embodiments, methods are provided for operating the circuit as described herein and for operating the lighting module and the lamp, respectively, according to the explanation given herein.

The approach introduced here allows for realizing a vastly temperature stable current source. In particular, a common current source may be wired using additional elements, so that a significantly improved temperature stability is reached for the overall system.

Further, a control loop is proposed allowing a feedback of the forward bias by the lighting unit to a supply voltage. This way it is feasible to reduce the power loss of the overall circuitry.

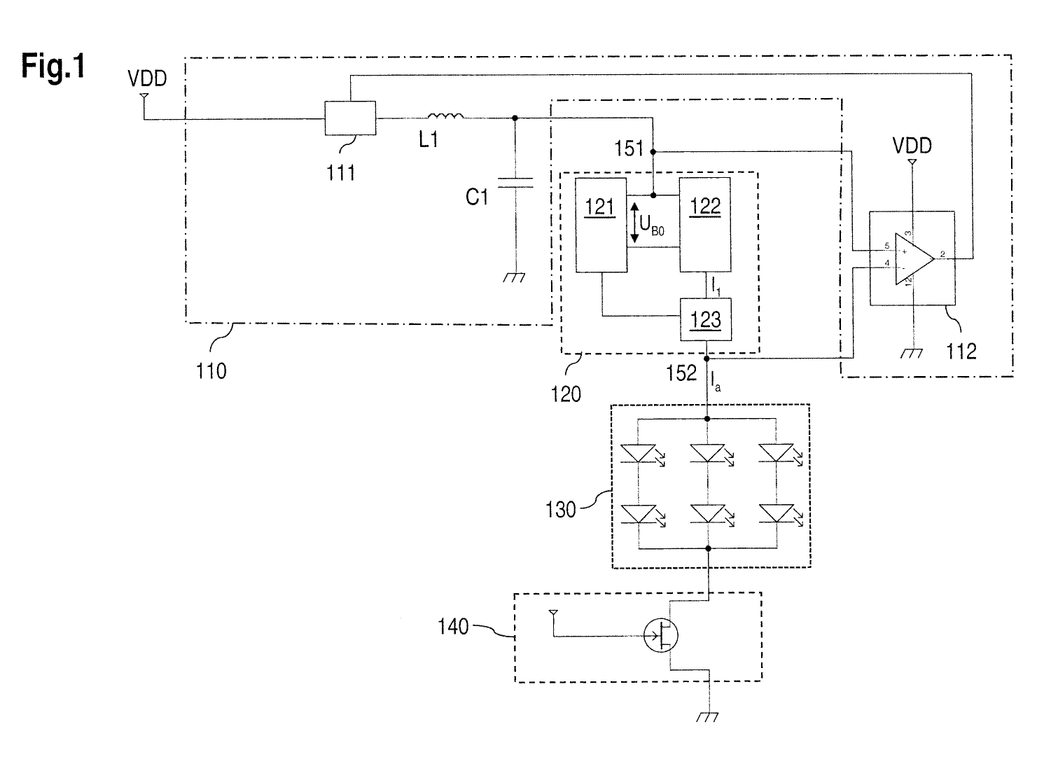

FIG. 1 shows a circuit comprising a vastly temperature compensated current source for operating a lighting unit.

A supply voltage is fed to a control unit 110 providing a input voltage for a unit 120 at a node 151.

Unit 120 comprises a temperature compensation unit 121, a current source 122 and a driver unit 123 which in particular is implemented in the form of an amplifier.

The voltage present at node 151 is supplied to the temperature compensation unit 121 as well as to the current source 122. The temperature compensation unit 121 as well as the current source are connected on their output sides to the driver unit 123 which delivers a current Iₐ for a lighting unit 130 via a node 152.

A voltage drop U_{B0} at the current source 122 is used to adjust the output current Iₐ at node 152 by means of the temperature compensation unit 121.

Lighting unit 130 preferably comprises a plurality of light emitting diodes. Here, the light emitting diodes may be connected in parallel, or connections in series comprising several light emitting diodes (so called strings) maybe connected in parallel to each other.

By means of a pulse-width modulation 140 connected downstream to the lighting unit 130 the brightness of lighting unit 130 is adjustable.

The above mentioned control unit 110 taps the voltages at nodes 151 and 152 and, dependent on the voltage difference, adjusts the input voltage at node 151 such that the downstream components may be operated with as little loss as possible. This may be achieved particularly in that this voltage difference is in accordance with the sum of the voltage drop of current source 122 and the voltage drop at driver unit 123, wherein the latter is determined such that the driver unit 123 generates as little power loss as possible. Preferably, this is the case if the voltage drop at driver unit 123 is just sufficient for the driver unit 123 to operate in its normal operation mode.

The adjustment of the voltage by means of control unit 110 is preferably being carried out such that the supply voltage VDD is fed to node 151 via a step-down converter (comprising a circuit 111, an inductor L1 and a capacitor C1).

The output of a comparator 112, whose inputs are connected to nodes 151 and 152, detects a voltage difference between these nodes 151 and 152 and dependent therefrom suitably controls step-down converter 111. Thus, it may be assured efficiently that as little unused voltage drop as possible occurs at driver unit 123 and consequently the power loss remains low.

From FIG. 1 arises that a cross current through the lighting unit 130 or a sum of cross currents through the strings of light emitting diodes of lighting unit 130 connected in series circulates through unit 120. The voltage drop at this unit 120 and between the nodes 151 and 152, respectively, determines a current I₁ impressed by current source 122.

For the conversion of the voltage drop between nodes 151 and 152 to current I₁ to be also effected largely independent of temperature, temperature compensation unit 121 is provided. To this end, temperature compensation unit 121 preferably has a temperature coefficient such that unit 120 provides a current for lighting unit 130 which is largely independent of the variations of temperature and in particular may be held constant also during warming of the components.

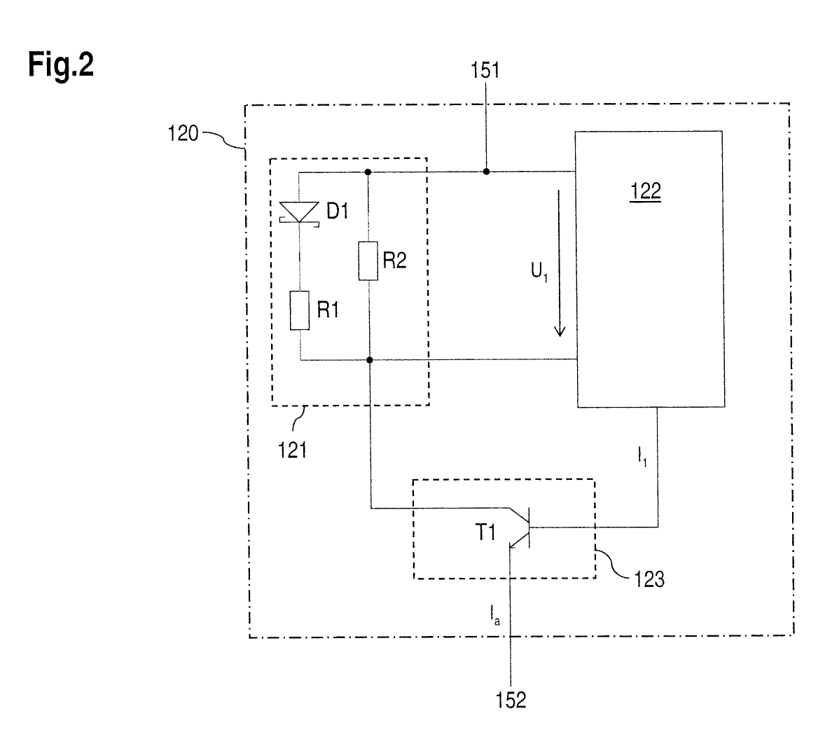

FIG. 2 shows a detailed representation of unit 120 comprising a possible embodiment of temperature compensation unit 121.

Unit 120 is arranged between nodes 151 and 152 (see FIG. 1). Temperature compensation unit 121 comprises a connection in series comprising a Schottky diode D1 (whose anode is connected to node 151) and a resistor R1, wherein this connection in series is arranged in parallel with a resistor R2. This parallel connection is connected to a collector of a npn transistor T1 in the direction to node 152. The base of transistor T1 is connected to the output of current source 122 and the emitter of transistor T1 is connected to node 152.

The parallel connection of the connection in series, comprising Schottky diode D1 and resistor R1, with resistor R2 is further arranged in parallel with current source 122.

Current source 122 varies its output current I₁ such that the voltage U₁ reaches a certain value. This output current I₁ in turn corresponds to the base current of transistor T1. For this reason, output current Iₐ is greater by the current amplification of transistor T1 than the output current I₁ of current source 122.

Without diode D1 shown in FIG. 2 the output current Iₐ Of the overall circuit would correspond to:

$${I}_{α} = {U}_{B 0} \cdot \frac{{R}_{1} + {R}_{2}}{{R}_{1} \cdot {R}_{2}} \cdot ( \frac{B + 1}{B} )$$

Parameter U_{B0} here corresponds to the above mentioned control voltage U₁ of FIG. 2.

The interrelationship between control voltage U₁ and U_{B0}, respectively, and output current I₁ of current source 122 is impinged on with a temperature coefficient. Therefrom arises that the output current Iₐ is dependent on temperature.

In order to reach temperature stability, temperature compensation unit 121 may be loaded with a temperature coefficient. This is preferably carried out by means of a device having a negative temperature coefficient. Examples for such devices are:
a diode;
a Schottky diode;
a high-temperature conductor.

In this connection current source 122 in particular has a negative temperature coefficient.

In FIG. 2 a Schottky diode is exemplified as a device having a negative temperature coefficient.

Both the Schottky diode D1 illustrated as well as the current source 122 have a negative temperature coefficient. By dimensioning the resistors R1 and R2 of FIG. 2 correspondingly the temperature dependency of the overall circuit may be eliminated virtually entirely for a given current. Hence it results:

$${R}_{2} = \frac{z \cdot {R}_{1}}{x - {yR}_{1}}$$

$${R}_{1} = \frac{{U}_{D 0} \cdot ( \frac{{α}_{AK}}{{α}_{UB}} - 1 )}{\frac{B}{B + 1} \cdot {I}_{α}}$$

$$with$$

$$z = {R}_{i} \cdot {α}_{UB} \cdot {U}_{B 0}$$

$$x = {R}_{i} \cdot ( {α}_{AK} \cdot {U}_{D 0} - {U}_{B 0} \cdot {α}_{UB} )$$

$$y = {U}_{B 0} \cdot {α}_{UB}$$

The parameters are to mean the following:
U_{D0} a forward voltage of Schottky diode D1;
U_{B0} a control voltage of current source 122 at 270K;
α_{UB} a temperature coefficient of current source 122;
α_{AK} a temperature coefficient of Schottky diode D1;
Rᵢ a (integrated) control resistor of current source 122;
B a current gain of transistor T1.

In a simulation with two BAT60A diodes (instead of the Schottky diode D1 of FIG. 2) connected in series, with a current source BCR401 and with a power transistor BCX56, a current deviation of 0.5% across a temperature range from 25° C. to 85° C. could be achieved (with R1=1.9 Ohm and R2=6.2 Ohm) at a nominal current of 350 mA.

### Further Advantages:

The approach suggested herein, by reason of the low device complexity, in particular allows the realization of a cost effective and temperature stable current source, which may be advantageously used for operating at least one lighting unit.

In particular, the at least one lighting unit comprises at least one light emitting diode, in particular at least one string comprising light emitting diodes connected in series. The at least one light emitting diode or the at least one string may each be connected in parallel repeatedly. Favorably, several of these lighting units each or repeatedly having different emission spectra may be coupled and/or wired to each other. By means of the highly stable current source a reproducible interaction of the different spectra of the LEDs may be achieved.

A further advantage exists in that the portion of the supply voltage not falling off across the light emitting diodes and across the temperature compensation unit, respectively, is falling off across the driver unit or is absorbed by a emitter-collector-path of a transistor, respectively. Due to the relatively high cross current this results in a significant power loss (for example, 350 mA at 1V voltage drop already result in 350 mW of power loss in the driver unit) since the supply voltage has to be preset as high such that also the light emitting diodes still may be operated with the highest possible forward voltage. By matching the supply voltage to the forward voltage of the lighting unit a significant reduction of the power loss may be achieved. Herefrom result an increase in durability as well as a improved reliability of the system.

### REFERENCE NUMERALS

110 control unit
111 circuit (part of a step-down converter)
112 comparator (comparation unit)
120 unit (comprising a temperature compensated current source comprising a driver unit)
121 temperature compensation unit
122 current source
123 driver unit or amplifier
130 lighting unit
140 (unit for) pulse-width modulation (for controlling the brightness of the lighting unit)
151 node
152 node
C1 capacitor
D1 diode, in particular Schottky diode
L1 inductor or coil
R1 resistor
R2 resistor
T1 npn transistor
VDD supply voltage

What is claimed is:

1. A circuit for adjusting and at least partially compensating, respectively, thermal variations, the circuit comprising:
a current source being connected to a temperature compensation unit,
wherein the temperature compensation unit at least partially compensates thermal variations of the current source, and
wherein the temperature compensation unit comprises at least one device having a temperature coefficient.

2. The circuit according to claim 1, wherein the temperature coefficient is a negative temperature coefficient.

3. The circuit according to claim 1, wherein a current of the current source is alterable.

4. The circuit according to claim 3, wherein a connection in series comprising the device and a first resistor is connected in parallel with a second resistor and a voltage falling off at this parallel connection serves as an input value for the current source.

5. The circuit according to claim 3, wherein the device comprises at least one of the following components:
a diode;
a Schottky diode;
a high-temperature conductor.

6. The circuit according to claim 1, wherein the current source provides a output current which may be amplified by means of a driver unit.

7. The circuit according to claim 6, wherein the temperature compensation unit is connected to the driver unit.

8. The circuit according to claim 6, wherein the current source and the temperature compensation unit are connected to a control unit for a input voltage.

9. The circuit according to claim 8, wherein the control unit is adjustable such that a voltage falling off across the current source and the driver unit results in no or marginal losses in the driver unit.

10. The circuit according to claim 10, wherein the voltage is adjustable such that the driver unit may reach a pre-selectable amplification.

11. The circuit according to claim 1, wherein an output current of the driver unit may be fed to at least one lighting unit.

12. The circuit according to claim 11, wherein the lighting unit comprises at least one of: at least one light emitting diode, at least one string comprised of light emitting diodes and a parallel circuit thereof.

13. The circuit according to claim 12, wherein the plurality of light emitting diodes are at least one of: of a same type and have substantially the same color.

14. The circuit according to claim 11, wherein a brightness of the lighting unit is adjustable by means of a pulse-width modulation.

15. A lighting module or a lamp with a circuit for adjusting and at least partially compensating, respectively, thermal variations, the lighting module comprising:
a current source being connected to a temperature compensation unit,
wherein the temperature compensation unit at least partially compensates thermal variations of the current source, and
wherein the temperature compensation unit comprises at least one device having a temperature coefficient.

16. The lighting module or lamp according to claim 15, comprising several lighting units.

17. The lighting module or lamp according to claim 15, wherein at least one of a brightness and a directional characteristic of the lighting modules and the lamp, respectively, is adjustable.

18. The lighting module or lamp according to claim 15, wherein a chromaticity coordinate is adjustable.

19. A method for operating a circuit comprising the steps of:
connecting a current source of the circuit to a temperature compensation unit of the circuit,
compensating at least partially thermal variations of the current source by the temperature compensation unit, wherein the temperature compensation unit comprises at least one device having a temperature coefficient.

20. A method for operating a lighting module or a lamp comprising the steps of:
arranging a circuit within said lighting module or lamp,
connecting a current source of the circuit to a temperature compensation unit of the circuit,
compensating at least partially thermal variations of the current source by the temperature compensation unit, wherein the temperature compensation unit comprises at least one device having a temperature coefficient.
